(19) United States
(12) Patent Application Publication
(10) Pub. No.: US 2022/0334483 A1
(43) Pub. Date: Oct. 20, 2022

(54) RESIST UNDERLAYER FILM-FORMING COMPOSITION

(71) Applicant: NISSAN CHEMICAL CORPORATION, Tokyo (JP)

(72) Inventors: Hiroto OGATA, Toyama-shi (JP); Hirokazu NISHIMAKI, Toyama-shi (JP); Makoto NAKAJIMA, Toyama-shi (JP)

(73) Assignee: NISSAN CHEMICAL CORPORATION, Tokyo (JP)

(21) Appl. No.: 17/641,852

(22) PCT Filed: Oct. 5, 2020
(86) PCT No.: PCT/JP2020/037711

§ 371 Date: Mar. 10, 2022

(30) Foreign Application Priority Data
Oct. 9, 2019 (JP) 2019-185975

(51) Int. Cl. G03F 7/11; C08G 61/02; H01L 21/027; H01L 21/3065

(52) U.S. Cl. CPC G03F 7/11; C08G 61/025; H01L 21/0275; H01L 21/3065

(57) ABSTRACT

A composition for forming a resist underlayer film exhibits strong etching resistance, has a good dry etching rate ratio and a good optical constant, and is capable of forming a film that provides good coverage over a so-called multilevel substrate and that is flat with reduced difference in thickness after embedding. A resist underlayer film uses said composition for forming a resist underlayer film; and a method for producing a semiconductor device. The composition for forming a resist underlayer film contains: a polymer having the partial structure represented by formula (1); and a solvent. (In the formula, Ar represents an optionally substituted C6-20 aromatic group.)

### TECHNICAL FIELD

The present invention relates to a resist underlayer film-forming composition that has high etching resistance and good optical constants, offers a useful dry etching rate ratio, and exhibits high coatability even with respect to the so-called stepped substrate and can bury the difference in level by forming a flat film having a small variation in film thickness. The present invention also relates to a resist underlayer film formed using the resist underlayer film-forming composition, and to a method for manufacturing a semiconductor device using the resist underlayer film-forming composition.

### BACKGROUND ART

In recent years, resist underlayer film materials for multilayer resist processes have been required to function as antireflection films particularly in short-wavelength exposure, to have an appropriate optical constant, and also to exhibit etching resistance during the processing of substrates. The use of polymers having repeating units containing a benzene ring has been proposed (Patent Literature 1).

### CITATION LIST

### Patent Literature

Patent Literature 1: JP 2004-354554 A

### SUMMARY OF INVENTION

### Technical Problem

To cope with the need for thinner resist layers stemming from the miniaturization of resist patterns, a lithography process, in which at least two resist underlayer films are formed and the resist underlayer films are used as mask materials, has been known. In this process, at least one organic film (organic underlayer film) and at least one inorganic underlayer film are formed on a semiconductor substrate. The inorganic underlayer film is patterned while using as a mask a resist pattern formed in an upper resist film, and the resultant pattern is used as a mask in the patterning of the organic underlayer film. The pattern formed in this manner attains a high aspect ratio. For example, the materials for forming the at least two layers are a combination of an organic resin (for example, an acrylic resin or a novolac resin) and an inorganic material (such as a silicon resin (for example, organopolysiloxane) or an inorganic silicon compound (for example, SiON or SiO₂)). In recent years, a double patterning technique, in which a single pattern is obtained through two times of lithography and two times of etching while using the multilayer process mentioned above in each of the steps, has widely been used. Here, the organic film formed after the first patterning is required to be capable of planarizing the difference in level.

Unfortunately, the coatability of resist underlayer film-forming compositions is poor with respect to the so-called stepped substrates that have unevenness due to the difference in height or density of a resist pattern disposed on the substrate to be processed. When a resist underlayer film-forming composition is applied to bury the difference in level, the resultant film tends to have a large variation in film thickness and not to be flat.

The present invention has been made based on the solution to these problems. An object of the present invention is therefore to provide a resist underlayer film-forming composition that has high etching resistance and good optical constants, offers a useful dry etching rate ratio, and exhibits good coatability even with respect to the so-called stepped substrate and can bury the difference in level by forming a flat film having a small variation in film thickness. Other objects of the present invention are to provide a resist underlayer film formed using the resist underlayer film-forming composition, and to provide a method for manufacturing a semiconductor device using the resist underlayer film-forming composition.

### Solution to Problem

The present invention embraces the following.

[1] A resist underlayer film-forming composition comprising a solvent and a polymer having a partial structure represented by the following formula (1):

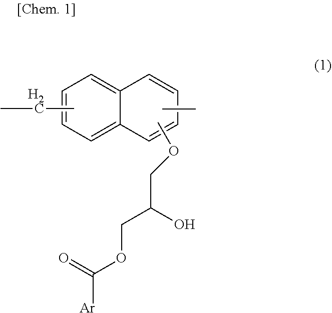

wherein Ar denotes an optionally substituted C6-C20 aromatic group.

[2] The resist underlayer film-forming composition according to [1], wherein Ar in formula (1) is a phenyl group, a naphthyl group, an anthracenyl group, a pyrenyl group or a combination of any of them.

[3] The resist underlayer film-forming composition according to [1], wherein Ar in formula (1) is a naphthyl group, an anthracenyl group or a combination thereof.

[4] The resist underlayer film-forming composition according to any one of [1] to [3], further comprising a crosslinking agent.

[5] The resist underlayer film-forming composition according to any one of [1] to [4], further comprising an acid and/or an acid generator.

[6] The resist underlayer film-forming composition according to [1], wherein the solvent has a boiling point of 160° C. or above.

[7] A resist underlayer film comprising a baked product of a coating film comprising the resist underlayer film-forming composition according to any one of [1] to [6].

[8] A method for manufacturing a semiconductor device, comprising the steps of:

forming on a semiconductor substrate a resist underlayer film using the resist underlayer film-forming composition according to any one of [1] to [6];

forming a resist film on the formed resist underlayer film;

irradiating the formed resist film with light or electron beam followed by development, to form a resist pattern;

etching the resist underlayer film through the formed resist pattern, to form a patterned resist underlayer film; and

processing the semiconductor substrate through the patterned resist underlayer film.

### Advantageous Effects of Invention

The resist underlayer film-forming composition of the present invention not only has high etching resistance and good optical constants, and offers a useful dry etching rate ratio, but also exhibits high coatability even with respect to the so-called stepped substrate and can bury the difference in level by forming a flat resist underlayer film having a small variation in film thickness, thus allowing for finer substrate processing.

In particular, the resist underlayer film-forming composition of the present invention is effective in a lithography process directed to reducing the resist film thickness in which at least two resist underlayer films are formed and the resist underlayer films are used as etching masks.

### DESCRIPTION OF EMBODIMENTS

[Resist Underlayer Film-Forming Compositions]

A resist underlayer film-forming composition according to the present invention includes a polymer having a partial structure represented by formula (1) below, a solvent and other components.

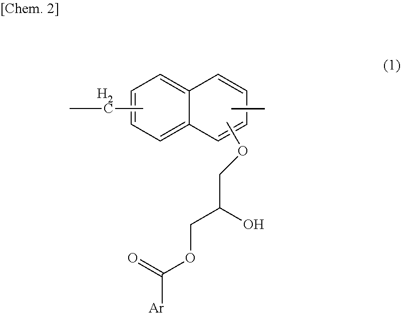

In the formula, Ar denotes an optionally substituted C6-C20 aromatic group. These components will be sequentially described below.

[Polymer Having a Partial Structure Represented by Formula (1)]

In the partial structure represented by formula (1), Ar denotes an optionally substituted C6-C20 aromatic group.

Examples of the C6-C20 aromatic groups include those derived from an optionally substituted aromatic compound by eliminating one of the hydrogen atoms.

The aromatic compounds may be:

(a) monocyclic compounds such as benzene,

(b) fused ring compounds such as naphthalene,

(c) heterocyclic compounds such as furan, thiophene and pyridine,

(d) compounds in which aromatic rings of the compounds (a) to (c) are bonded via a single bond, such as biphenyl, or

(e) compounds in which aromatic rings of two or more compounds selected from the compounds (a) to (d) are connected via one, or two or more types of spacers represented by, for example, —(CH₂)ₙ— (n=1 to 20), —CH═CH—, —C≡C—, —N═N—, —NH—, —NR—, —NHCO—, —NRCO—, —S—, —COO—, —O—, —CO— or —CH═N—, such as phenylnaphthylamine. Two or more spacers may be connected together.

Specific examples of the aromatic compounds include benzene, toluene, xylene, mesitylene, cumene, styrene, indene, naphthalene, azulene, anthracene, phenanthrene, naphthacene, triphenylene, pyrene, chrysene, thiophene, furan, pyridine, pyrimidine, pyrazine, pyrrole, oxazole, thiazole, imidazole, naphthalene, anthracene, quinoline, carbazole, quinazoline, purine, indolizine, benzothiophene, benzofuran, indole, phenylindole and acridine.

The aromatic groups may be mono-substituted or poly-substituted with at least one substituent selected from the group consisting of halogen atoms, C1-C20 alkyl groups, fused ring groups, heterocyclic groups, hydroxy groups, amino groups, nitro groups, ether groups, alkoxy groups, cyano groups and carboxyl groups.

Examples of the halogen atoms include fluorine atom, chlorine atom, bromine atom and iodine atom.

Examples of the C1-C20 alkyl groups include optionally substituted, linear or branched alkyl groups such as, for example, methyl group, ethyl group, n-propyl group, isopropyl group, n-butyl group, sec-butyl group, tert-butyl group, n-pentyl group, isopentyl group, neopentyl group, n-hexyl group, isohexyl group, n-heptyl group, n-octyl group, cyclohexyl group, 2-ethylhexyl group, n-nonyl group, isononyl group, p-tert-butylcyclohexyl group, n-decyl group, n-dodecylnonyl group, undecyl group, dodecyl group, tridecyl group, tetradecyl group, pentadecyl group, hexadecyl group, heptadecyl group, octadecyl group, nonadecyl group and eicosyl group. Examples of the cycloalkyl groups include cyclopropyl group, cyclobutyl group, cyclopentyl group, cyclohexyl group, cycloheptyl group and cyclooctyl group, each of which may be optionally substituted.

C1-C12 alkyl groups are preferable, C1-C8 alkyl groups are more preferable, and C1-C4 alkyl groups are still more preferable.

The C1-C20 alkyl groups may be interrupted with an oxygen atom, a sulfur atom or an amide bond, with examples including those containing a structural unit represented by —CH₂—O—, —CH₂—S—, —CH₂—NHCO— or —CH₂—CONH—. The alkyl groups may contain one unit or two or more units represented by —O—, —S—, —NHCO— or —CONH—. Specific examples of the C1-C20 alkyl groups interrupted with an —O—, —S—, —NHCO— or —CONH— unit include methoxy group, ethoxy group, propoxy group, butoxy group, methylthio group, ethylthio group, propylthio group, butylthio group, methylcarbonylamino group, ethyl carbonylamino group, propylcarbonylamino group, butyl carbonylamino group, methylaminocarbonyl group, ethylaminocarbonyl group, propylaminocarbonyl group and butylaminocarbonyl group. They further include methyl group, ethyl group, propyl group, butyl group, pentyl group, hexyl group, heptyl group, octyl group, nonyl group, decyl group, dodecyl group and octadecyl group, each of which are substituted with a substituent such as a methoxy group, an ethoxy group, a propoxy group, a butoxy group, a methylthio group, an ethylthio group, a propylthio group, a butylthio group, a methylcarbonylamino group, an ethylcarbonylamino group, a methylaminocarbonyl group or an ethylaminocarbonyl group. Methoxy group, ethoxy group, methylthio group and ethylthio group are preferable, and methoxy group and ethoxy group are more preferable.

The fused ring groups are substituents derived from a fused ring compound. Specific examples thereof include phenyl group, naphthyl group, anthracenyl group, phenanthrenyl group, naphthacenyl group, triphenylenyl group, pyrenyl group and chrysenyl group. Of these, phenyl group, naphthyl group, anthracenyl group and pyrenyl group are preferable.

The heterocyclic groups are substituents derived from a heterocyclic compound. Specific examples thereof include thiophene group, furan group, pyridine group, pyrimidine group, pyrazine group, pyrrole group, oxazole group, thiazole group, imidazole group, quinoline group, carbazole group, quinazoline group, purine group, indolizine group, benzothiophene group, benzofuran group, indole group, acridine group, isoindole group, benzimidazole group, isoquinoline group, quinoxaline group, cinnoline group, pteridine group, chromene group (benzopyran group), isochromene group (benzopyran group), xanthene group, thiazole group, pyrazole group, imidazoline group and azine group. Of these, thiophene group, furan group, pyridine group, pyrimidine group, pyrazine group, pyrrole group, oxazole group, thiazole group, imidazole group, quinoline group, carbazole group, quinazoline group, purine group, indolizine group, benzothiophene group, benzofuran group, indole group and acridine group are preferable. Thiophene group, furan group, pyridine group, pyrimidine group, pyrrole group, oxazole group, thiazole group, imidazole group and carbazole group are most preferable.

Ar is preferably a phenyl group, a naphthyl group, an anthracenyl group or a pyrenyl group, and more preferably a naphthyl group or an anthracenyl group.

When the polymer having a partial structure of formula (1) has more than one Ar group in the molecule, the Ar groups may be the same as or different from one another.

The polymer may include a partial structure other than the partial structure represented by formula (1) in an amount that does not impair the advantageous effects of the present invention (for example, less than 50% by mole, less than 30% by mole, less than 20% by mole, less than 10% by mole or less than 5% by mole).

The mass ratio of the Ar groups relative to the whole of the polymer is usually within the range of 1:0.1 to 1:0.5, and preferably 1:0.15 to 1:0.4.

The weight average molecular weight Mw of the polymer having a partial structure of formula (1) is usually 4,400 or less, preferably 2,200 or less, and more preferably 1,100 or less, and is usually 500 or more.

[Synthesis Methods]

The polymer having a partial structure of formula (1) may be obtained by reacting a main chain polymer having at least one epoxy group in the molecule with an aromatic carboxylic acid under appropriate conditions.

Examples of the main chain polymers having at least one epoxy group in the molecule include:

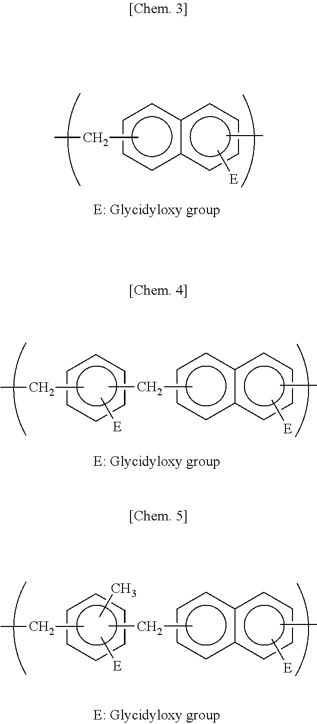

For example, NC-7300L (produce name, manufactured by Nippon Kayaku Co., Ltd.) is available. The polymer may include a glycidyl-free aromatic unit as long as the advantageous effects of the present invention are not impaired.

Examples of the aromatic carboxylic acids include benzoic acid, 1-naphthalenecarboxylic acid, 9-anthracenecarboxylic acid and 1-pyrenecarboxylic acid.

The reaction may be carried out in an appropriate solvent in the presence of an appropriate catalyst.

The solvent is not particularly limited as long as the solvent can uniformly dissolve the main chain polymer having at least one epoxy group in the molecule and the aromatic carboxylic acid, and does not inhibit the reaction or induce side reactions.

Examples thereof include ethylene glycol monomethyl ether, ethylene glycol monoethyl ether, methylcellosolve acetate, ethylcellosolve acetate, diethylene glycol monomethyl ether, diethylene glycol monoethyl ether, propylene glycol, propylene glycol monoethyl ether, propylene glycol monomethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide and N,N-dimethyl acetamide. The solvents may be used alone or in combination of two or more. Of the solvents mentioned above, propylene glycol monomethyl ether, propylene glycol monomethyl ether acetate, ethyl lactate, butyl lactate and cyclohexanone are preferable.

Examples of the catalysts include quaternary ammonium salts such as tetrabutylammonium bromide, quaternary phosphonium salts such as ethyltriphenylphosphonium bromide, and phosphine compounds such as triphenylphosphine. Ethyltriphenylphosphonium bromide is preferable.

The reaction temperature is usually within the range of 40° C. to 200° C. The amount of reaction time is variable and is selected in accordance with the reaction temperature, but is usually within the range of about 30 minutes to 50 hours.

Cation exchange resins and anion exchange resins for catalysts may be used in order to prevent any undesired substances such as unreacted acids, catalysts and inactivated catalysts from remaining in the reaction system.

[Solvents]

The solvent used in the resist underlayer film-forming composition according to the present invention is not particularly limited as long as the solvent can dissolve the reaction product described above. In particular, in view of the fact that the resist underlayer film-forming composition of the present invention is used as a uniform solution and also in consideration of the applicability of the composition, it is recommended to use a combination of solvents generally used in the lithography process.

Examples of such solvents include methylcellosolve acetate, ethylcellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol and y-butyrolactone. The solvents may be used alone or in combination of two or more.

Further, the following compounds according to WO 2018/131562A1 may also be used.

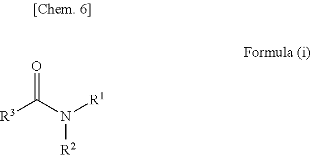

In formula (i), R¹, R² and R³ each denote a hydrogen atom or a C1-C20 alkyl group optionally interrupted with an oxygen atom, a sulfur atom or an amide bond, are the same as or different from one another, and are optionally bonded together to form a ring structure.

Examples of the C1-C20 alkyl groups include optionally substituted, linear or branched alkyl groups such as, for example, methyl group, ethyl group, n-propyl group, isopropyl group, n-butyl group, sec-butyl group, tert-butyl group, n-pentyl group, isopentyl group, neopentyl group, n-hexyl group, isohexyl group, n-heptyl group, n-octyl group, cyclohexyl group, 2-ethylhexyl group, n-nonyl group, isononyl group, p-tert-butylcyclohexyl group, n-decyl group, n-dodecylnonyl group, undecyl group, dodecyl group, tridecyl group, tetradecyl group, pentadecyl group, hexadecyl group, heptadecyl group, octadecyl group, nonadecyl group and eicosyl group. C1-C12 alkyl groups are preferable, C1-C8 alkyl groups are more preferable, and C1-C4 alkyl groups are still more preferable.

Examples of the C1-C20 alkyl groups interrupted with an oxygen atom, a sulfur atom or an amide bond include those containing a structural unit represented by —CH₂—O—, —CH₂—S—, —CH₂—NHCO— or —CH₂—CONH—. The alkyl groups may contain one unit or two or more units represented by —O—, —S—, —NHCO— or —CONH—. Specific examples of the C1-C20 alkyl groups interrupted with an —O—, —S—, —NHCO— or —CONH— unit include methoxy group, ethoxy group, propoxy group, butoxy group, methylthio group, ethylthio group, propylthio group, butylthio group, methylcarbonylamino group, ethylcarbonylamino group, propylcarbonylamino group, butylcarbonylamino group, methylaminocarbonyl group, ethylaminocarbonyl group, propylaminocarbonyl group and butylaminocarbonyl group, and further include methyl group, ethyl group, propyl group, butyl group, pentyl group, hexyl group, heptyl group, octyl group, nonyl group, decyl group, dodecyl group and octadecyl group which are each substituted with a sub stituent such as a methoxy group, an ethoxy group, a propoxy group, a butoxy group, a methylthio group, an ethylthio group, a propylthio group, a butylthio group, a methylcarbonylamino group, an ethylcarbonylamino group, a methylaminocarbonyl group or an ethylaminocarbonyl group. Methoxy group, ethoxy group, methylthio group and ethylthio group are preferable, and methoxy group and ethoxy group are more preferable.

The solvents mentioned above have a relatively high boiling point and are therefore effective for imparting high gap-filling properties and high flattening properties to the resist underlayer film-forming composition.

Specific examples of preferred compounds represented by formula (i) are illustrated below:

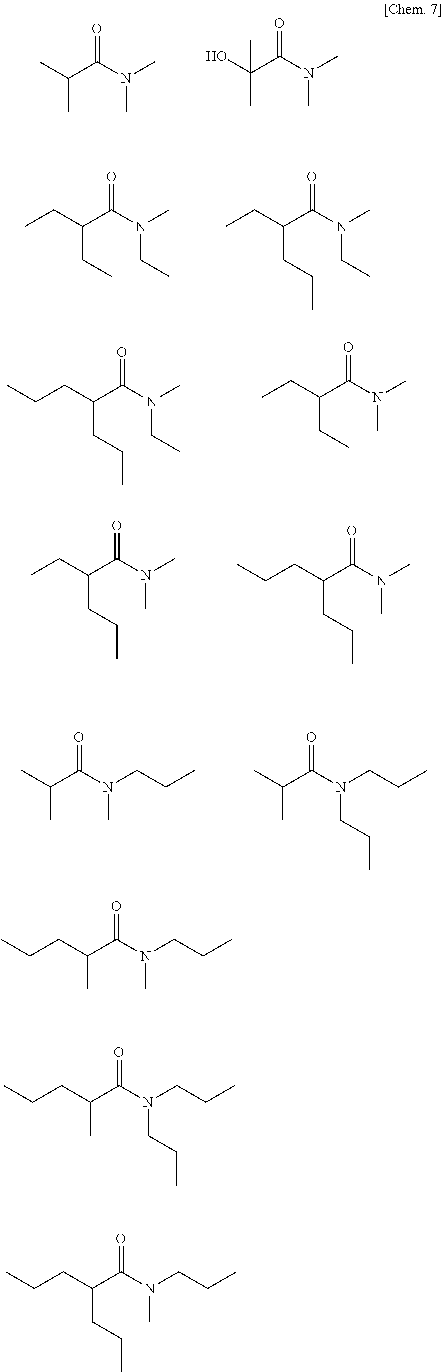

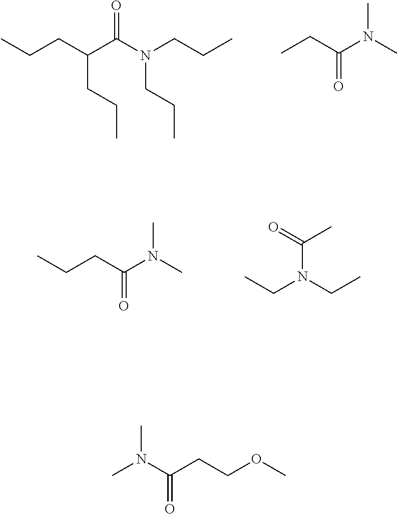

Of the compounds illustrated above, 3-methoxy-N,N-dimethylpropionamide, N,N-dimethylisobutyramide, and the compounds represented by the following formulas are preferable.

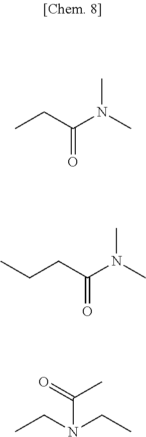

Particularly preferred compounds represented by formula (i) are 3-methoxy-N,N-dimethylpropionamide and N,N-dimethylisobutyramide.

The solvents mentioned above may be used alone or in combination of two or more. Of these solvents, those having a boiling point of 160° C. or above are preferable. Some preferred solvents are propylene glycol monomethyl ether, propylene glycol monomethyl ether acetate, ethyl lactate, butyl lactate, cyclohexanone, 3-methoxy-N,N-dimethylpropionamide, N,N-dimethylisobutyramide, 2,5-dimethylhexane-1,6-diyl diacetate (DAH; cas, 89182-68-3) and 1,6-diacetoxyhexane (cas, 6222-17-9). Propylene glycol monomethyl ether, propylene glycol monomethyl ether acetate and N,N-dimethylisobutyramide are particularly preferable.

[Crosslinking Agent Components]

The resist underlayer film-forming composition of the present invention may include a crosslinking agent component. Examples of the crosslinking agents include melamine compounds, substituted urea compounds, and polymers thereof. Those crosslinking agents having at least two crosslinking substituents are preferable, with examples including methoxymethylated glycoluril (for example, tetramethoxymethyl glycoluril), butoxymethylated glycoluril, methoxymethylated melamine, butoxymethylated melamine, methoxymethylated benzoguanamine, butoxymethylated benzoguanamine, methoxymethylated urea, butoxymethylated urea and methoxymethylated thiourea. Further, condensates of these compounds may also be used.

The crosslinking agent that is used may be a crosslinking agent having high heat resistance. The crosslinking agent having high heat resistance may be suitably a compound that contains, in the molecule, a crosslinking substituent having an aromatic ring (for example, a benzene ring or a naphthalene ring).

Examples of such compounds include compounds having a partial structure of the following formula (4), and polymers or oligomers having a repeating unit of the following formula (5):

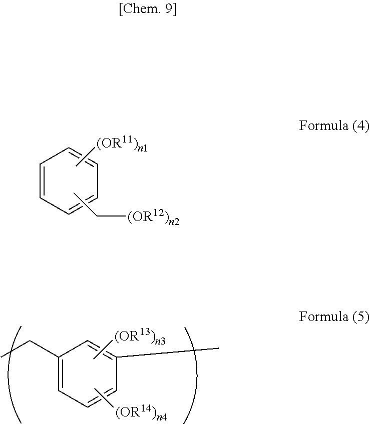

R¹¹, R¹², R¹³ and R¹⁴ are each a hydrogen atom or a C1-C10 alkyl group. Examples of the alkyl groups include those described hereinabove.

Examples of the compounds, the polymers and the oligomers of formula (4) and formula (5) include the following:

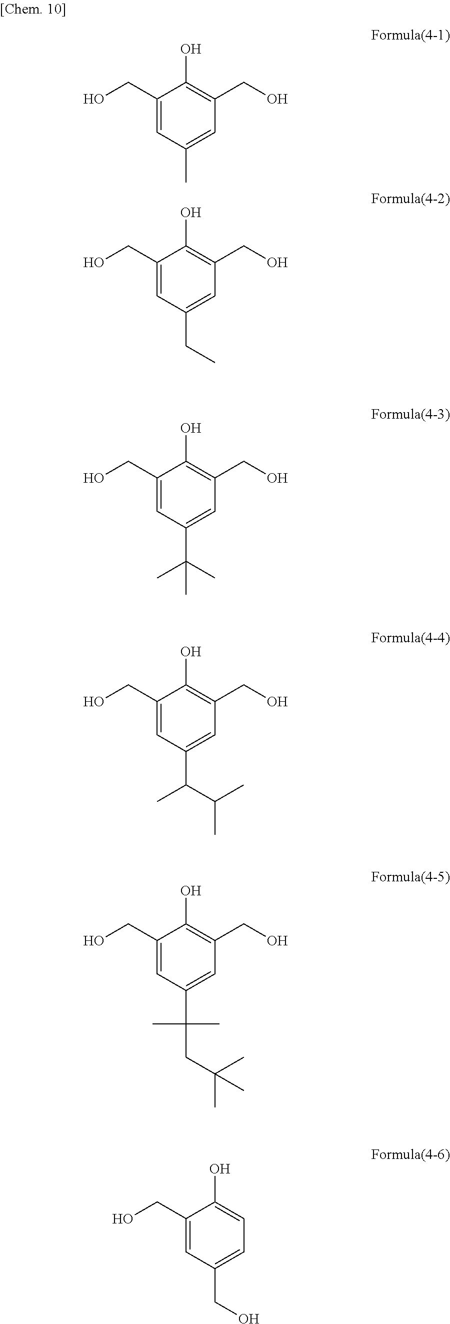

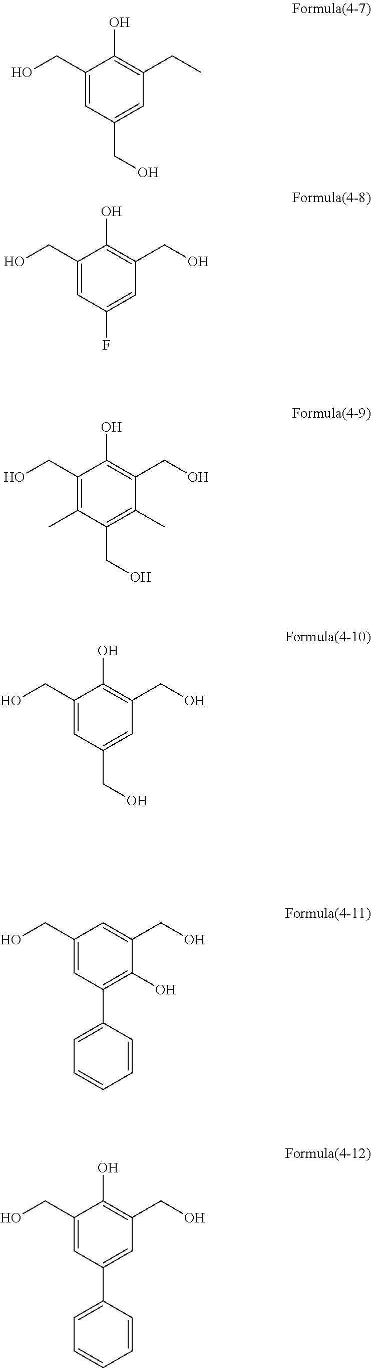 [SMILES: CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

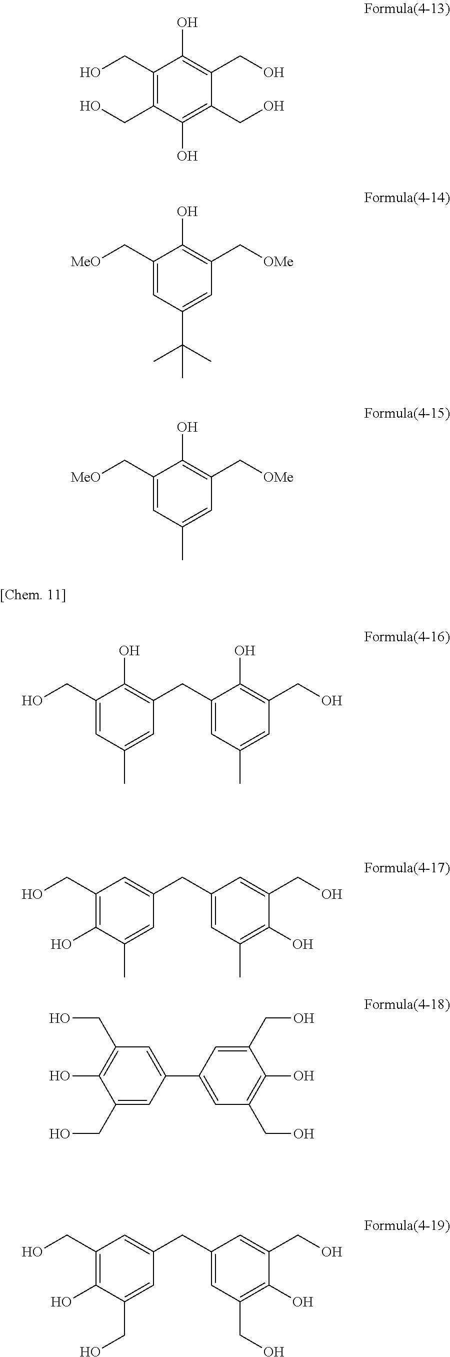

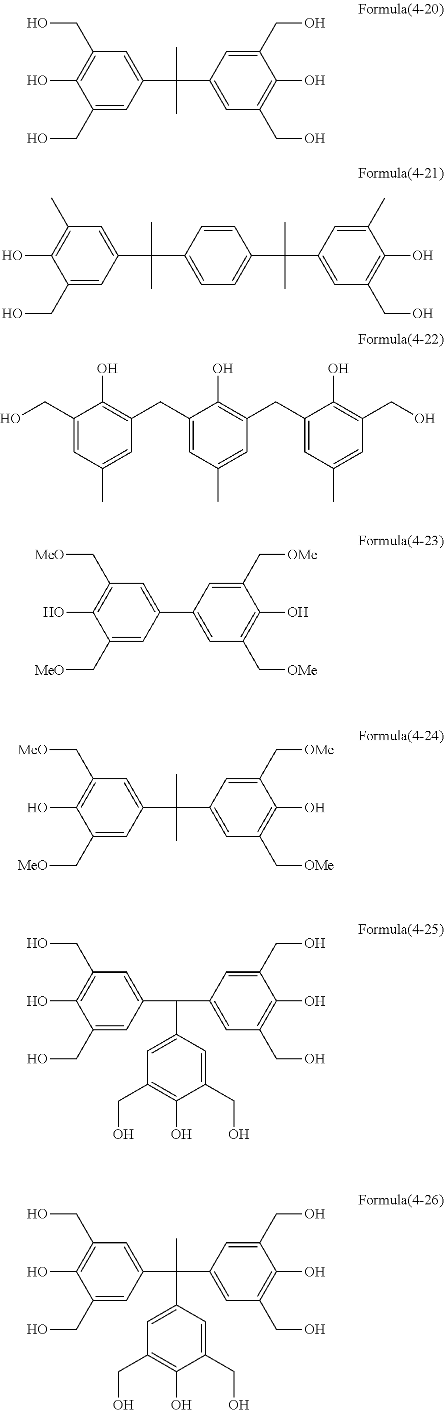

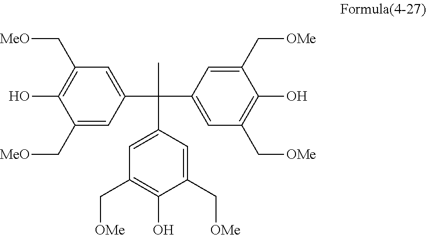 [SMILES: COCc1cc(C(C)(c2cc(COC)c(O)c(COC)c2)c2cc(COC)c(O)c(COC)c2)cc(COC)c1O]

The compounds mentioned above may be obtained as products of ASAHI YUKIZAI CORPORATION and Honshu Chemical Industry Co., Ltd. Of the crosslinking agents illustrated above, for example, the compound of formula (4-23) is available under the produce name TMOM-BP from Honshu Chemical Industry Co., Ltd., and the compound of formula (4-24) is available under the produce name TM-BIP-A from ASAHI YUKIZAI CORPORATION.

The amount added of the crosslinking agent varies depending on factors such as the coating solvent that is used, the base substrate that is used, the required solution viscosity and the required film shape, but may be 0.001% by mass or more, 0.01% by mass or more, 0.05% by mass or more, 0.5% by mass or more, or 1.0% by mass or more, and may be 80% by mass or less, 50% by mass or less, 40% by mass or less, 20% by mass or less, or 10% by mass or less of the total solid content. The crosslinking agents mentioned above may sometimes undergo crosslinking reaction by self-condensation, but when the polymer of the present invention contains crosslinking substituents, the crosslinking agents can react with any of the crosslinking substituents to cause a crosslinking reaction.

[Acids and/or Acid Generators]

The resist underlayer film-forming composition of the present invention may contain an acid and/or an acid generator.

Examples of the acids include p-toluenesulfonic acid, trifluoromethanesulfonic acid, pyridinium p-toluenesulfonic acid, pyridinium phenolsulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid and naphthalenecarboxylic acid.

The acids may be used alone or in combination of two or more. The amount is usually in the range of 0.0001 to 20% by mass, preferably 0.0005 to 10% by mass, and more preferably 0.01 to 5% by mass based on the total solid content.

Examples of the acid generators include thermal acid generators and photo acid generators.

Examples of the thermal acid generators include 2,4,4,6-tetrabromocyclohexadienone, benzoin tosylate, 2-nitrobenzyl tosylate, K-PURE (registered trademark) series CXC-1612, CXC-1614, TAG-2172, TAG-2179, TAG-2678, TAG 2689 and TAG 2700 (manufactured by King Industries), SI-45, SI-60, SI-80, SI-100, SI-110 and SI-150 (manufactured by SANSHIN CHEMICAL INDUSTRY CO., LTD.), and other organosulfonic acid alkyl esters.

The photo acid generator generates an acid when the resist is exposed to light, thereby allowing the acidity of the underlayer film to be adjusted. The use of the photo acid generator is an approach to adjusting the acidity of the underlayer film to the acidity of a resist layer that is formed thereon. Further, the shape of a pattern formed in the upper resist layer may be controlled by the adjustment of the acidity of the underlayer film.

Examples of the photo acid generators contained in the resist underlayer film-forming compositions of the present invention include onium salt compounds, sulfonimide compounds and disulfonyl diazomethane compounds.

Examples of the onium salt compounds include iodonium salt compounds such as diphenyliodonium hexafluorophosphate, diphenyliodonium trifluoromethanesulfonate, diphenyliodonium nonafluoro-normal butane sulfonate, diphenyliodonium perfluoro-normal octane sulfonate, diphenyliodonium camphorsulfonate, bis(4-tert-butylphenyl)iodonium camphorsulfonate and bis(4-tert-butylphenyl)iodonium trifluoromethanesulfonate, and sulfonium salt compounds such as triphenylsulfonium hexafluoroantimonate, triphenylsulfonium nonafluoro-normal butane sulfonate, triphenylsulfonium camphorsulfonate and triphenylsulfonium trifluoromethanesulfonate.

Examples of the sulfonimide compounds include N-(trifluoromethanesulfonyloxy)succinimide, N-(nonafluoro-normal butane sulfonyloxy)succinimide, N-(camphorsulfonyloxy)succinimide and N-(trifluoromethanesulfonyloxy)naphthalimide.

Examples of the disulfonyl diazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane and methyl sulfonyl-p-toluenesulfonyldiazomethane.

The acid generators may be used alone or in combination of two or more.

When the acid generator is used, the ratio thereof is in the range of 0.01 to 10 parts by mass, 0.1 to 8 parts by mass, or 0.5 to 5 parts by mass per 100 parts by mass of the solid content in the resist underlayer film-forming composition.

[Other Components]

To reduce the occurrence of defects such as pinholes or striation and to further enhance the applicability to surface unevenness, the resist underlayer film-forming composition of the present invention may further include a surfactant. Examples of the surfactant include nonionic surfactants such as polyoxyethylene alkyl ethers including polyoxyethylene lauryl ether, polyoxyethylene stearyl ether, polyoxyethylene cetyl ether and polyoxyethylene oleyl ether, polyoxyethylene alkylaryl ethers including polyoxyethylene octylphenol ether and polyoxyethylene nonylphenol ether, polyoxyethylene/polyoxypropylene block copolymers, sorbitan fatty acid esters including sorbitan monolaurate, sorbitan monopalmitate, sorbitan monostearate, sorbitan monooleate, sorbitan trioleate and sorbitan tristearate, and polyoxyethylene sorbitan fatty acid esters including polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate, fluorosurfactants such as EFTOP series EF301, EF303 and EF352 (produce names, manufactured by Mitsubishi Materials Electronic Chemicals Co., Ltd.), MEGAFACE series F171, F173, R-40, R-40N and R-40LM (produce names, manufactured by DIC CORPORATION), Fluorad series FC430 and FC431 (produce names, manufactured by Sumitomo 3M Limited), AsahiGuard AG710, and Surflon series S-382, SC101, SC102, SC103, SC104, SC105 and SC106 (produce names, manufactured by AGC Inc.), and organosiloxane polymer KP341 (manufactured by Shin-Etsu Chemical Co., Ltd.). The amount added of the surfactant is usually 2.0% by mass or less, and preferably 1.0% by mass or less based on the total solid content of the resist underlayer film materials. The surfactants may be used alone or in combination of two or more. When the surfactant is used, the ratio thereof is in the range of 0.0001 to 5 parts by mass, 0.001 to 1 part by mass, or 0.01 to 0.5 parts by mass per 100 parts by mass of the solid content in the resist underlayer film-forming composition.

Other components such as light absorbers, rheology modifiers and adhesion aids may be added to the resist underlayer film-forming composition of the present invention. Rheology modifiers are effective for enhancing the fluidity of the underlayer film-forming composition. Adhesion aids are effective for enhancing the adhesion between an underlayer film and a semiconductor substrate or a resist.

Some examples of the light absorbers suitably used are commercially available light absorbers according to “Kougyouyou Shikiso no Gijutsu to Shijou (Technology and Market of Industrial Dyes)” (CMC Publishing Co., Ltd.) and “Senryou Binran (Dye Handbook)” (edited by The Society of Synthetic Organic Chemistry, Japan), such as, for example, C. I. Disperse Yellow 1, 3, 4, 5, 7, 8, 13, 23, 31, 49, 50, 51, 54, 60, 64, 66, 68, 79, 82, 88, 90, 93, 102, 114 and 124; C. I. Disperse Orange 1, 5, 13, 25, 29, 30, 31, 44, 57, 72 and 73; C. I. Disperse Red 1, 5, 7, 13, 17, 19, 43, 50, 54, 58, 65, 72, 73, 88, 117, 137, 143, 199 and 210; C. I. Disperse Violet 43; C. I. Disperse Blue 96; C. I. Fluorescent Brightening Agent 112, 135 and 163; C. I. Solvent Orange 2 and 45; C. I. Solvent Red 1, 3, 8, 23, 24, 25, 27 and 49; C. I. Pigment Green 10; and C. I. Pigment Brown 2. The light absorber is usually added in a proportion of 10% by mass or less, and preferably 5% by mass or less based on the total solid content in the resist underlayer film-forming composition.

The rheology modifier may be added mainly to enhance the fluidity of the resist underlayer film-forming composition and thereby, particularly in the baking step, to increase the uniformity in thickness of the resist underlayer film and to enhance the filling performance of the resist underlayer film-forming composition with respect to the inside of holes. Specific examples thereof include phthalic acid derivatives such as dimethyl phthalate, diethyl phthalate, diisobutyl phthalate, dihexyl phthalate and butyl isodecyl phthalate; adipic acid derivatives such as di-n-butyl adipate, diisobutyl adipate, diisooctyl adipate and octyl decyl adipate; maleic acid derivatives such as di-n-butyl maleate, diethyl maleate and dinonyl maleate; oleic acid derivatives such as methyl oleate, butyl oleate and tetrahydrofurfuryl oleate; and stearic acid derivatives such as n-butyl stearate and glyceryl stearate. The rheology modifier is usually added in a proportion of less than 30% by mass relative to the total solid content in the resist underlayer film-forming composition.

The adhesion aid may be added mainly to enhance the adhesion between the resist underlayer film-forming composition and a substrate or a resist and thereby to prevent the detachment of the resist particularly during development. Specific examples thereof include chlorosilanes such as trimethylchlorosilane, dimethylmethylolchlorosilane, methyldiphenylchlorosilane and chloromethyldimethylchlorosilane; alkoxysilanes such as trimethylmethoxysilane, dimethyldiethoxysilane, methyldimethoxysilane, dimethylmethylolethoxysilane, diphenyldimethoxysilane and phenyltriethoxysilane; silazanes such as hexamethyldisilazane, N,N′-bis(trimethylsilyl)urea, dimethyltrimethylsilylamine and trimethylsilylimidazole; silanes such as methyloltrichlorosilane, γ-chloropropyltrimethoxysilane, γ-aminopropyltriethoxysilane and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracyl, mercaptoimidazole and mercaptopyrimidine; and urea or thiourea compounds such as 1,1-dimethylurea and 1,3-dimethylurea. The adhesion aid is usually added in a proportion of less than 5% by mass, and preferably less than 2% by mass relative to the total solid content in the resist underlayer film-forming composition.

The solid content in the resist underlayer film-forming composition according to the present invention is usually in the range of 0.1 to 70% by mass, and preferably 0.1 to 60% by mass. The solid content is the proportion of all the components of the resist underlayer film-forming composition except the solvent. The proportion of the polymer in the solid content may be in the range of 1 to 100% by mass, 1 to 99.9% by mass, 50 to 99.9% by mass, 50 to 95% by mass, or 50 to 90% by mass in the order of increasing preference.

One of the measures for evaluating whether the resist underlayer film-forming composition is a uniform solution is to pass the composition through a predetermined microfilter. The resist underlayer film-forming composition according to the present invention may be passed through a microfilter having a pore size of 0.2 μm, and shows a uniform solution state.

Examples of the microfilter materials include fluororesins such as PTFE (polytetrafluoroethylene) and PFA (tetrafluoroethylene/perfluoroalkyl vinyl ether copolymer), PE (polyethylene), UPE (ultrahigh molecular weight polyethylene), PP (polypropylene), PSF (polysulfone), PES (polyethersulfone) and nylon, with PTFE (polytetrafluoroethylene) being preferable.

[Resist Underlayer Film and Method for Manufacturing Semiconductor Device]

Hereinbelow, the resist underlayer film from the resist underlayer film-forming composition of the present invention, and the method for manufacturing semiconductor device will be described.

The resist underlayer film-forming composition of the present invention is applied with an appropriate technique such as a spinner or a coater onto a semiconductor device substrate (such as, for example, a silicon wafer substrate, a silicon/silicon dioxide coated substrate, a silicon nitride substrate, a glass substrate, an ITO substrate, a polyimide substrate, or a low dielectric constant material (low-k material) coated substrate), and the coating is baked to form a resist underlayer film. The baking conditions are appropriately selected from baking temperatures of 80° C. to 400° C. and amounts of baking time of 0.3 to 60 minutes. The baking temperature is preferably 150° C. to 350° C., and the baking time is preferably 0.5 to 2 minutes. Here, the film thickness of the underlayer film that is formed is, for example, in the range of 10 to 1000 nm, or 20 to 500 nm, or 30 to 400 nm, or 50 to 300 nm.

Further, an inorganic resist underlayer film (a hard mask) may be formed on the organic resist underlayer film according to the present invention. For example, such a hard mask may be formed by spin-coating of a silicon-containing resist underlayer film (inorganic resist underlayer film) forming composition according to WO 2009/104552 A1, or by CVD of a Si-based inorganic material.

The resist underlayer film-forming composition according to the present invention may be applied onto a semiconductor substrate having a stepped region and a stepless region (the so-called stepped substrate) and may be baked to form a resist underlayer film having a difference in level in the range of 3 to 70 nm between the stepped region and the stepless region.

Next, a resist film, for example, a photoresist layer is formed on the resist underlayer film. The photoresist layer may be formed by a well-known method, specifically, by applying a photoresist composition solution onto the underlayer film followed by baking. The film thickness of the photoresist is, for example, in the range of 50 to 10,000 nm, or 100 to 2,000 nm, or 200 to 1,000 nm.

The photoresist applied onto the resist underlayer film is not particularly limited as long as it is sensitive to light used in the photoexposure. Negative photoresists and positive photoresists may be used. Examples include positive photoresists composed of a novolac resin and a 1,2-naphthoquinonediazide sulfonic acid ester; chemically amplified photoresists composed of a photo acid generator and a binder having a group that is decomposed by an acid to increase the alkali dissolution rate; chemically amplified photoresists composed of an alkali-soluble binder, a photo acid generator, and a low-molecular compound that is decomposed by an acid to increase the alkali dissolution rate of the photoresist; and chemically amplified photoresists composed of a photo acid generator, a binder having a group that is decomposed by an acid to increase the alkali dissolution rate, and a low-molecular compound that is decomposed by an acid to increase the alkali dissolution rate of the photoresist. Specific examples include those available under the product names of APEX-E from Shipley, PAR 710 from Sumitomo Chemical Co., Ltd., and SEPR 430 from Shin-Etsu Chemical Co., Ltd. Examples further include fluorine-containing polymer-based photoresists according to Proc. SPIE, Vol. 3999, 330-334 (2000), Proc. SPIE, Vol. 3999, 357-364 (2000), and Proc. SPIE, Vol. 3999, 365-374 (2000).

Next, a resist pattern is formed by light or electron beam irradiation and development. First, the resist is photoexposed through a predetermined mask. For example, a near ultraviolet ray, a far ultraviolet ray, or an extreme ultraviolet ray (e.g., EUV (wavelength: 13.5 nm)) may be used for the photoexposure. Specifically, among others, KrF excimer laser beam (wavelength: 248 nm), ArF excimer laser beam (wavelength: 193 nm) or F₂ excimer laser beam (wavelength: 157 nm) may be used. Of these, ArF excimer laser beam (wavelength: 193 nm) and EUV (wavelength: 13.5 nm) are preferable. After the photoexposure, post-exposure baking may be performed as required. The post-exposure baking is performed under conditions appropriately selected from baking temperatures of 70° C. to 150° C. and amounts of baking time of 0.3 to 10 minutes.

In the present invention, the above resist, i.e., the photoresist may be replaced by an electron beam lithographic resist. The electron beam resists may be negative or positive. Examples include chemically amplified resists composed of an acid generator and a binder having a group that is decomposed by an acid to give rise to a change in alkali dissolution rate; chemically amplified resists composed of an alkali-soluble binder, an acid generator, and a low-molecular compound that is decomposed by an acid to change the alkali dissolution rate of the resist; chemically amplified resists composed of an acid generator, a binder having a group that is decomposed by an acid to give rise to a change in alkali dissolution rate, and a low-molecular compound that is decomposed by an acid to change the alkali dissolution rate of the resist; non-chemically amplified resists composed of a binder having a group that is decomposed by an electron beam to give rise to a change in alkali dissolution rate; and non-chemically amplified resists composed of a binder having a moiety that is cleaved by an electron beam to give rise to a change in alkali dissolution rate. The electron beam resist may be patterned using an electron beam as the irradiation source in the same manner as when the photoresist is used.

Next, the resist is developed with a developing solution. When, for example, the resist is a positive photoresist, the portions of the photoresist that have been photoexposed are removed to leave a photoresist pattern.

Examples of the developing solutions include alkaline aqueous solutions, for example, aqueous solutions of alkali metal hydroxides such as potassium hydroxide and sodium hydroxide, aqueous solutions of quaternary ammonium hydroxides such as tetramethylammonium hydroxide, tetraethylammonium hydroxide and choline, and aqueous solutions of amines such as ethanolamine, propylamine and ethylenediamine. Further, additives such as surfactants may be added to the developing solutions. The development conditions are appropriately selected from temperatures of 5 to 50° C. and amounts of time of 10 to 600 seconds.

After the photoresist (the upper layer) has been patterned as described above, the inorganic underlayer film (the intermediate layer) is removed using the pattern as a protective film, and thereafter the organic underlayer film (the lower layer) is removed using as a protective film the film consisting of the patterned photoresist and the patterned inorganic underlayer film (intermediate layer). Lastly, the semiconductor substrate is processed using as a protective film the patterned inorganic underlayer film (intermediate layer) and the patterned organic underlayer film (lower layer).

First, the portions of the inorganic underlayer film (the intermediate layer) exposed from the photoresist are removed by dry etching to expose the semiconductor substrate. The dry etching of the inorganic underlayer film may be performed using a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane or dichloroborane. A halogen-containing gas is preferably used in the dry etching of the inorganic underlayer film, and a fluorine-containing gas is more preferably used. Examples of the fluorine-containing gases include tetrafluoromethane (CF₄), perfluorocyclobutane (C₄F₈), perfluoropropane (C₃F₈), trifluoromethane and difluoromethane (CH₂F₂).

Thereafter, the organic underlayer film is removed using as a protective film the film consisting of the patterned photoresist and the patterned inorganic underlayer film. The organic underlayer film (the lower layer) is preferably removed by dry etching using an oxygen-containing gas for the reason that the inorganic underlayer film containing a large amount of silicon atoms is hardly removed by dry etching with an oxygen-containing gas.

Lastly, the semiconductor substrate is processed. The semiconductor substrate is preferably processed by dry etching with a fluorine-containing gas.

Examples of the fluorine-containing gases include tetrafluoromethane (CF₄), perfluorocyclobutane (C₄F₈), perfluoropropane (C₃F₈), trifluoromethane and difluoromethane (CH₂F₂).

Before the formation of the photoresist, an organic antireflective film may be formed on the upper layer of the resist underlayer films. The antireflective coating composition used herein is not particularly limited and may be appropriately selected from those conventionally used in the lithographic process. The antireflective film may be formed by a conventional method, for example, by application with a spinner or a coater followed by baking.

In the present invention, an organic underlayer film may be formed on a substrate, thereafter an inorganic underlayer film may be formed thereon, and further a photoresist may be formed thereon. By such a configuration, processing of the substrate becomes possible by selecting an appropriate etching gas, even when the photoresist is designed with a narrow pattern width and is formed with a small thickness to avoid collapsing of the pattern. For example, the resist underlayer films may be processed using as the etching gas a fluorine-containing gas capable of etching the photoresist at a sufficiently high rate; the substrate may be processed using as the etching gas a fluorine-containing gas capable of etching the inorganic underlayer film at a sufficiently high rate; and further the substrate may be processed using as the etching gas an oxygen-containing gas capable of etching the organic underlayer film at a sufficiently high rate.

The resist underlayer film formed from the resist underlayer film-forming composition sometimes shows absorption with respect to the light used in the lithographic process, depending on the wavelength of the light. In such cases, the film can function as an antireflective film to effectively prevent the reflection of light from the substrate. Further, the underlayer film formed from the resist underlayer film-forming composition of the present invention can also function as a hard mask. The underlayer film of the present invention may be used as, for example, a layer for preventing the interaction between a substrate and a photoresist, a layer having a function to prevent adverse effects on a substrate by a material used in a photoresist or by a substance generated during the photoexposure of a photoresist, a layer having a function to prevent the diffusion of substances generated from a substrate during heating and baking into an upper photoresist layer, and a barrier layer for reducing the poisoning effects on a photoresist layer by a semiconductor substrate dielectric layer.

Further, the underlayer film formed from the resist underlayer film-forming composition may be used as a gap-filling material that is applied to a substrate with via holes used in the dual damascene process and can fill the holes without clearance. Furthermore, the underlayer film may also be used as a flattening material for flattening the surface of an irregular semiconductor substrate.

### EXAMPLES

Specific examples of the resist underlayer film-forming compositions of the present invention will be described hereinbelow with reference to the following Examples. However, it should be construed that the scope of the present invention is not limited thereto.

The equipment such as apparatus used for the measurement of the weight average molecular weight of reaction products obtained in Synthesis Examples are described below.

Apparatus: HLC-8320 GPC manufactured by Tosoh Corporation

GPC columns: TSKgel Super-Multipore HZ-N (two columns)

Column temperature: 40° C.

Flow rate: 0.35 ml/min

Eluent: THF

Standard samples: Polystyrenes

The following are the chemical structures (illustrative) and the abbreviations of representative raw materials used.

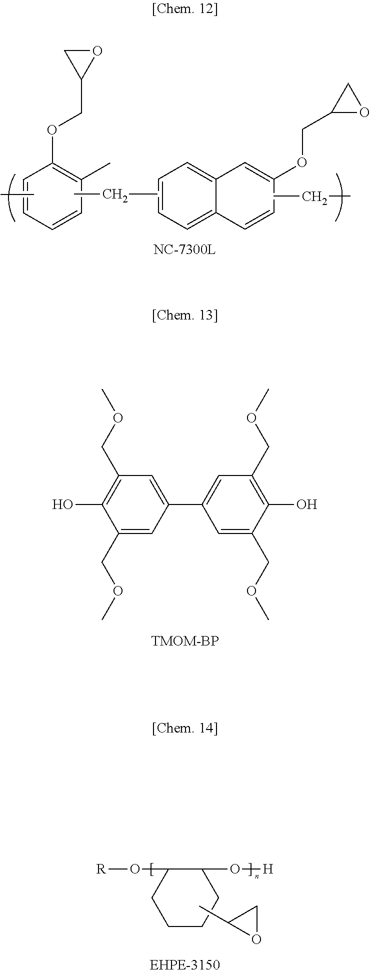

### Synthesis Example 1

6.00 g of NC-7300L (product name, manufactured by Nippon Kayaku Co., Ltd.), 4.91 g of 1-naphthalenecarboxylic acid (manufactured by Tokyo Chemical Industry Co., Ltd.) and 0.26 g of ethyltriphenylphosphonium bromide as a catalyst were added to 26.07 g of propylene glycol monomethyl ether (hereinafter, abbreviated as PGME in this specification). The resultant mixture was allowed to react at 140° C. for 24 hours to give a solution containing the reaction product. Thereto were added 12.00 g of an anion exchange resin (product name: DOWEX [registered trademark] MONOSPHERE [registered trademark] 550A, Muromachi Technos Co., Ltd.) and 12.00 g of a cation exchange resin (product name: AMBERLYST [registered trademark] 15JWET, ORGANO CORPORATION). The resultant mixture was stirred at 25° C. to 30° C. for 4 hours and was then filtered.

GPC analysis showed that the thus obtained reaction product had a weight average molecular weight of 770 relative to standard polystyrenes. The reaction product obtained is estimated to be a copolymer having a structural unit represented by the following formula (1):

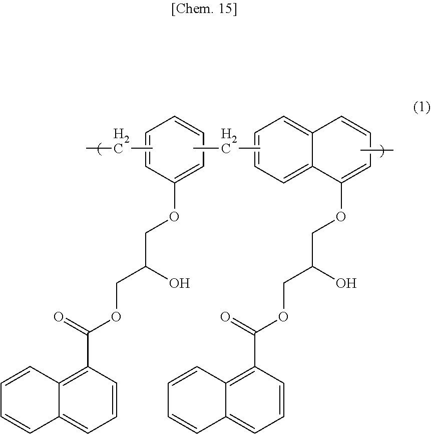

### Synthesis Example 2

6.00 g of NC-7300L (product name, manufactured by Nippon Kayaku Co., Ltd.), 6.33 g of 9-anthracenecarboxylic acid (manufactured by Midori Kagaku Co., Ltd.) and 0.26 g of ethyltriphenylphosphonium bromide as a catalyst were added to 26.07 g of PGME. The resultant mixture was allowed to react at 140° C. for 24 hours to give a solution containing the reaction product. Thereto were added 13.00 g of an anion exchange resin (product name: DOWEX [registered trademark] MONOSPHERE [registered trademark] 550A, Muromachi Technos Co., Ltd.) and 13.00 g of a cation exchange resin (product name: AMBERLYST [registered trademark] 15JWET, ORGANO CORPORATION). The resultant mixture was stirred at 25° C. to 30° C. for 4 hours and was then filtered.

GPC analysis showed that the thus obtained reaction product had a weight average molecular weight of 830 relative to standard polystyrenes. The reaction product obtained is estimated to be a copolymer having a structural unit represented by the following formula (2):

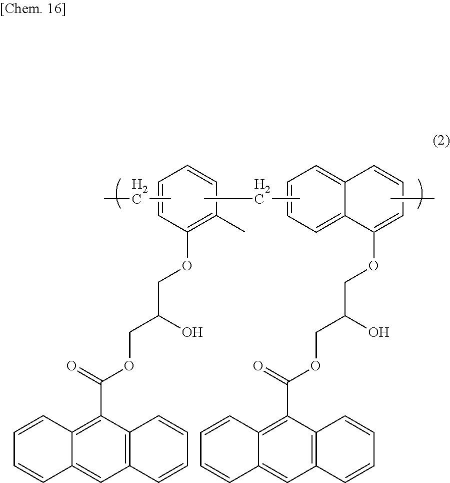

### Synthesis Example 3

6.00 g of NC-7300L (product name, manufactured by Nippon Kayaku Co., Ltd.), 3.48 g of benzoic acid (manufactured by Tokyo Chemical Industry Co., Ltd.) and 0.26 g of ethyltriphenylphosphonium bromide as a catalyst were added to 22.74 g of PGME. The resultant mixture was allowed to react at 140° C. for 24 hours to give a solution containing the reaction product. Thereto were added 10.00 g of an anion exchange resin (product name: DOWEX [registered trademark] MONOSPHERE [registered trademark] 550A, Muromachi Technos Co., Ltd.) and 10.00 g of a cation exchange resin (product name: AMBERLYST [registered trademark] 15JWET, ORGANO CORPORATION). The resultant mixture was stirred at 25° C. to 30° C. for 4 hours and was then filtered.

GPC analysis showed that the thus obtained reaction product had a weight average molecular weight of 750 relative to standard polystyrenes. The reaction product obtained is estimated to be a copolymer having a structural unit represented by the following formula (4):

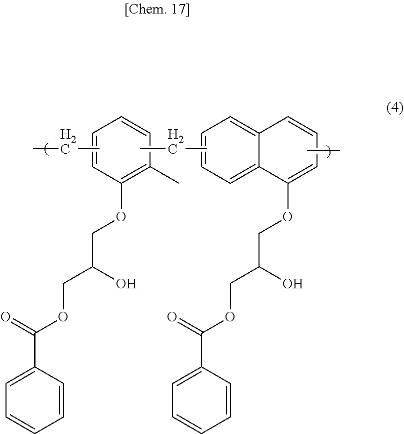

### Synthesis Example 4

5.00 g of NC-7300L (product name, manufactured by Nippon Kayaku Co., Ltd.), 5.85 g of 1-pyrenecarboxylic acid (manufactured by Tokyo Chemical Industry Co., Ltd.) and 0.22 g of ethyltriphenylphosphonium bromide as a catalyst were added to 25.83 g of PGME. The resultant mixture was allowed to react at 140° C. for 24 hours to give a solution containing the reaction product. Thereto were added 11.00 g of an anion exchange resin (product name: DOWEX [registered trademark] MONOSPHERE [registered trademark] 550A, Muromachi Technos Co., Ltd.) and 11.00 g of a cation exchange resin (product name: AMBERLYST [registered trademark] 15JWET, ORGANO CORPORATION). The resultant mixture was stirred at 25° C. to 30° C. for 4 hours and was then filtered.

GPC analysis showed that the thus obtained reaction product had a weight average molecular weight of 720 relative to standard polystyrenes. The reaction product obtained is estimated to be a copolymer having a structural unit represented by the following formula (5):

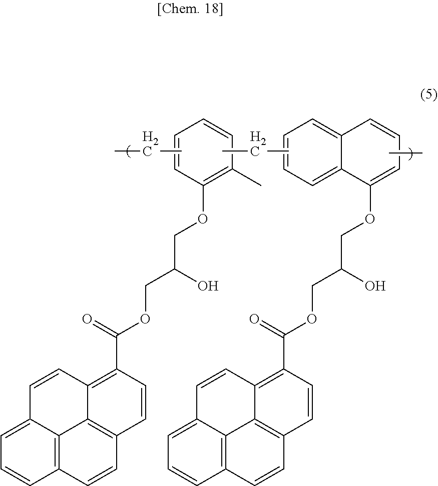

### Comparative Synthesis Example 1

17.67 g of propylene glycol monomethyl ether acetate (hereinafter, abbreviated as PGMEA in this specification), 5.00 g of EHPE-3150 (product name, manufactured by Daicel Corporation), 3.11 g of 9-anthracenecarboxylic acid, 2.09 g of benzoic acid and 0.62 g of ethyltriphenylphosphonium bromide were added to 7.57 g of PGME. The mixture was heated under reflux in a nitrogen atmosphere for 13 hours. To the resultant solution were added 16 g of a cation exchange resin (product name: AMBERLYST [registered trademark] 15JWET, ORGANO CORPORATION) and 16 g of an anion exchange resin (product name: DOWEX [registered trademark] MONOSPHERE [registered trademark] 550A, Muromachi Technos Co., Ltd.). The resultant mixture was stirred at 25° C. to 30° C. for 4 hours and was then filtered.

GPC analysis showed that the thus obtained reaction product had a weight average molecular weight of 4,700 relative to standard polystyrenes. The reaction product obtained is estimated to be a copolymer having a structural unit represented by the following formula (3):

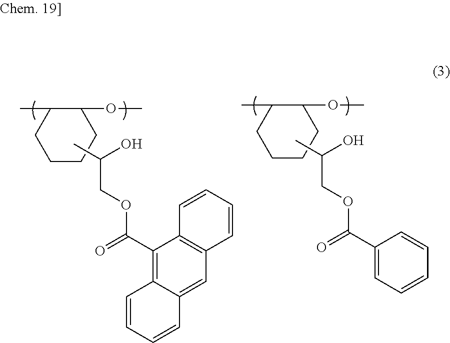

[Preparation of Resist Underlayer Film-Forming Composition]

### Example 1

4.90 g of a solution containing 1.26 g of the copolymer obtained in Synthesis Example 1 (the solvent was PGME, and the solid content was 25.74% by mass) was mixed together with 0.25 g of TMOM-BP (product name, manufactured by Honshu Chemical Industry Co., Ltd.), 2.52 g of a 1% by mass PGME solution of K-PURE [registered trademark] TAG2689 (product name, manufactured by King Industries), 6.66 g of PGME, 5.54 g of PGMEA and 0.13 g of a 1% by mass PGME solution of a surfactant (product name: R-30N, manufactured by DIC CORPORATION), thus forming a 7.7% by mass solution. The solution was filtered through a polytetrafluoroethylene microfilter having a pore size of 0.2 μm. A resist underlayer film-forming composition was thus prepared.

### Example 2

4.63 g of a solution containing 1.26 g of the copolymer obtained in Synthesis Example 2 (the solvent was PGME, and the solid content was 27.23% by mass) was mixed together with 0.25 g of TMOM-BP (product name, manufactured by Honshu Chemical Industry Co., Ltd.), 2.52 g of a 1% by mass PGME solution of K-PURE [registered trademark] TAG2689 (product name, manufactured by King Industries), 6.93 g of PGME, 5.54 g of PGMEA and 0.13 g of a 1% by mass PGME solution of a surfactant (product name: R-30N, manufactured by DIC CORPORATION), thus forming a 7.7% by mass solution. The solution was filtered through a polytetrafluoroethylene microfilter having a pore size of 0.2 μm. A resist underlayer film-forming composition was thus prepared.

### Example 3

5.06 g of a solution containing 1.26 g of the copolymer obtained in Synthesis Example 3 (the solvent was PGME, and the solid content was 24.95% by mass) was mixed together with 0.25 g of TMOM-BP (product name, manufactured by Honshu Chemical Industry Co., Ltd.), 2.52 g of a 1% by mass PGME solution of K-PURE [registered trademark] TAG2689 (product name, manufactured by King Industries), 6.51 g of PGME, 5.54 g of PGMEA and 0.13 g of a 1% by mass PGME solution of a surfactant (product name: R-30N, manufactured by DIC CORPORATION), thus forming a 7.7% by mass solution. The solution was filtered through a polytetrafluoroethylene microfilter having a pore size of 0.2 μm. A resist underlayer film-forming composition was thus prepared.

### Example 4

4.19 g of a solution containing 1.26 g of the copolymer obtained in Synthesis Example 4 (the solvent was PGME, and the solid content was 30.12% by mass) was mixed together with 0.25 g of TMOM-BP (product name, manufactured by Honshu Chemical Industry Co., Ltd.), 2.52 g of a 1% by mass PGME solution of K-PURE [registered trademark] TAG2689 (product name, manufactured by King Industries), 7.37 g of PGME, 5.54 g of PGMEA and 0.13 g of a 1% by mass PGME solution of a surfactant (product name: R-30N, manufactured by DIC CORPORATION), thus forming a 7.7% by mass solution. The solution was filtered through a polytetrafluoroethylene microfilter having a pore size of 0.2 μm. A resist underlayer film-forming composition was thus prepared.

### Comparative Example 1

19.52 g of a solution containing 4.51 g of the copolymer obtained in Comparative Synthesis Example 1 (the solvent was PGME/PGMEA mixed solvent, the same as that used at the time of synthesis, and the solid content was 23.26% by mass) was mixed together with 1.14 g of tetramethoxymethylglycoluril (product name: POWDERLINK [registered trademark] 1174, manufactured by Cytec Industries Incorporated, Japan), 3.41 g of a 1% by mass PGME solution of pyridinium p-toluenesulfonate, 50.68 g of PGME, 14.80 g of PGMEA and 0.45 g of a 1% by mass PGME solution of a surfactant (product name: R-30, manufactured by DIC CORPORATION), thus forming a 6.35% by mass solution. The solution was filtered through a polytetrafluoroethylene microfilter having a pore size of 0.2 μm. A resist underlayer film-forming composition was thus prepared.

[Test of Dissolution into Photoresist Solvents]

Each of the resist underlayer film-forming compositions prepared in Examples 1 to 4 and Comparative Example 1 was applied onto a silicon wafer using a spinner. The coating was baked on a hot plate at a temperature according to Table 1 below for 1 minute to form a resist underlayer film (film thickness: 0.2 μm). The resist underlayer film was soaked in a PGME/PGMEA mixed solvent (mixing ratio by mass: 70/30), which was used for photoresist solutions. The resist underlayer films were insoluble in the solvent. The results are indicated as “AA” in Table 1 below.

[Test of Optical Parameters]

Each of the resist underlayer film-forming compositions prepared in Examples 1 to 4 and Comparative Example 1 was applied onto a silicon wafer using a spinner. The coating was baked on a hot plate at a temperature according to Table 1 below for 1 minute to form a resist underlayer film (film thickness: 0.2 μm). The resist underlayer film was analyzed with an optical ellipsometer (VUV-VASE VU-302 manufactured by J. A. Woollam) to measure the refractive index (n value) and the attenuation coefficient (k value) at a wavelength of 193 nm. The results are shown in Table 1 below. To ensure for the resist underlayer film to exhibit a sufficient antireflection function, the k value at a wavelength of 193 nm is desirably 0.1 or more and 0.4 or less.

[Measurement of Dry Etching Rate]

Each of the resist underlayer film-forming compositions prepared in Examples 1 to 4 and Comparative Example 1 was applied onto a silicon wafer in the same manner as described above to form a resist underlayer film. The dry etching rate of the resist underlayer film was measured with an RIE system manufactured by Samco Inc., using CF₄ as a dry etching gas. The dry etching rate of the resist underlayer film was converted to a relative value when the dry etching rate of Comparative Example 1 was taken as 1.00. The results are shown as the “relative dry etching rate” in Table 1 below. The resist underlayer film from each of the resist underlayer film-forming compositions prepared in Examples 1 to 2 had a sufficiently slower dry etching rate as compared to the dry etching rate of Comparative Example 1. These results indicate that use of the resist underlayer film-forming composition according to the invention as a mask would facilitate the processing of the substrate.

TABLE 1

| | | Solvent | | | | | |
|---|---|---|---|---|---|---|---|
| | Baking | resistance | Optical parameters | | | | |
| | temperature | PGME/PGMEA | 193 nm | | Etching | Gap-filling | |
| | (deg. C.) | 70/30 | n value | k value | resistance | properties | Flatness |
| Example 1 | 250 | ∘ | 1.38 | 0.40 | 0.82 | ∘ | ∘ |
| Example 2 | 250 | ∘ | 1.46 | 0.36 | 0.82 | ∘ | ∘ |
| Example 3 | 250 | ∘ | 1.46 | 0.60 | 0.86 | ∘ | ∘ |
| Example 4 | 250 | ∘ | 1.49 | 0.58 | 0.75 | ∘ | ∘ |
| Comparative | 215 | ∘ | 1.64 | 0.26 | 1.00 | x | x |
| Example 1 | | | | | | | |

[Evaluation of Gap-Filling Property]

Gap-filling property was evaluated using a 200 nm thick SiO₂ substrate having a dense pattern area consisting of 50 nm wide trenches at 100 nm pitches. Each of the resist underlayer film-forming compositions prepared in Examples 1 to 2 and Comparative Examples 1 to 3 was applied onto the substrate, and the coating was baked under predetermined conditions to form a resist underlayer film having a thickness of about 200 nm. The flatness of the substrate was observed using a scanning electron microscope (S-4800) manufactured by Hitachi High-Tech Corporation to confirm whether the resist underlayer film-forming composition had filled the inside of the pattern. Good gap-filling propertiy was obtained in Examples 1 to 2 and Comparative Examples 2 to 3, but voids were found in Comparative Example 1.

[Test of Coatability on Stepped Substrate]

To evaluate the coatability on a stepped substrate, the thickness of a coating film formed on a 200 nm thick SiO₂ substrate was compared between on a dense pattern area (DENSE) consisting of 50 nm wide trenches at 100 nm pitches and on an open area (OPEN) free from such patterns. Each of the resist underlayer film-forming compositions from Examples 1 to 2 and Comparative Examples 1 to 3 was applied onto the substrate to form a 150 nm thick film, which was then baked at a predetermined temperature. The coatability of the film onto the stepped substrate was observed with a scanning electron microscope (S-4800) manufactured by Hitachi High-Tech Corporation to measure the difference in film thickness between on the dense area (the patterned area) and on the open area (the pattern-free area) of the stepped substrate (the difference in level present on the film between the dense area and the open area, called the bias), to evaluate the flattening property. The film thicknesses in each of the areas, and the difference in level present on the film are shown in Table 2. In the evaluation of flatness, the smaller the value of bias, the higher the flattening property.

TABLE 2

| | DENSE | OPEN | DENSE/OPEN |
|---|---|---|---|
| | Film thickness | Film thickness | Difference in level |
| | (nm) | (nm) | (nm) |
| Example 1 | 101 | 135 | 34 |
| Example 2 | 95 | 143 | 48 |
| Example 3 | 105 | 133 | 28 |
| Example 4 | 95 | 149 | 54 |
| Comparative | 70 | 145 | 75 |
| Example 1 | | | |

### INDUSTRIAL APPLICABILITY

The resist underlayer film-forming composition provided according to the present invention has high etching resistance and good optical constants, offers a useful dry etching rate ratio, and exhibits high coatability even on the so-called stepped substrate and can bury the difference in level by forming a flat film having a small variation in film thickness. The present invention also provides a resist underlayer film formed using the resist underlayer film-forming composition, and a method for manufacturing a semiconductor device using the resist underlayer film-forming composition.

1. A resist underlayer film-forming composition comprising a solvent and a polymer having a partial structure represented by the following formula (1): 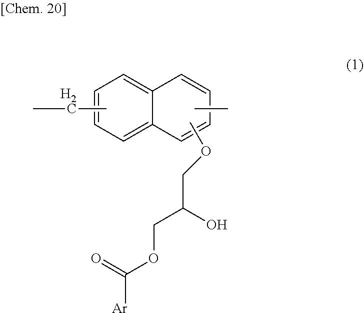
wherein Ar denotes an optionally substituted C6-C20 aromatic group.

2. The resist underlayer film-forming composition according to claim 1, wherein Ar in formula (1) is a phenyl group, a naphthyl group, an anthracenyl group, a pyrenyl group or a combination of any of them.

3. The resist underlayer film-forming composition according to claim 1, wherein Ar in formula (1) is a naphthyl group, an anthracenyl group or a combination thereof.

4. The resist underlayer film-forming composition according to claim 1, further comprising a crosslinking agent.

5. The resist underlayer film-forming composition according to claim 1, further comprising an acid and/or an acid generator.

6. The resist underlayer film-forming composition according to claim 1, wherein the solvent has a boiling point of 160° C. or above.

7. A resist underlayer film, which is a baked product of a coating film comprising the resist underlayer film-forming composition according to claim 1.

8. A method for manufacturing a semiconductor device, comprising the steps of:
forming on a semiconductor substrate a resist underlayer film using the resist underlayer film-forming composition according to claim 1;
forming a resist film on the formed resist underlayer film;
irradiating the formed resist film with light or electron beam followed by development, to form a resist pattern;
etching the resist underlayer film through the formed resist pattern, to form a patterned resist underlayer film; and
processing the semiconductor substrate through the patterned resist underlayer film.
